(19) United States
(12) Patent Application Publication
(10) Pub. No.: US 2017/0031399 A1
(43) Pub. Date: Feb. 2, 2017

(54) MOTHERBOARD WITH MULTIPLE CHIPS

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventor: MENG-LIANG YANG, Shenzhen (CN)

(21) Appl. No.: 14/834,733

(22) Filed: Aug. 25, 2015

(30) Foreign Application Priority Data
Jul. 28, 2015 (CN) 201510460917.4

(51) Int. Cl. G06F 1/26; H03K 17/687

(52) U.S. Cl. CPC G06F 1/26; H03K 17/687

(57) ABSTRACT

A motherboard includes a first signal module and a second signal module, a first switch module and a second switch module, a first enable module and a second enable module, an input interface, and a control module. The control module outputs different control signal to the first and second switch modules. The first switch is used to connect the first enable module to the first signal module or to the input interface corresponding to the control signals. The second switch is used to connect the second enable module to the second signal module or to the input interface corresponding to the control signals.

### FIELD

The subject matter herein generally relates to a motherboard with multiple chips.

### BACKGROUND

When needing to be programmed, a chip on a motherboard should be removed first.

### BRIEF DESCRIPTION OF THE DRAWINGS

Implementations of the present technology will now be described, by way of example only, with reference to the attached figures.

FIG. 1 is a circuit diagram of an embodiment of a motherboard.

FIG. 2 is a circuit diagram of power terminals of the motherboard in FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently coupled or releasably coupled. The term “comprising,” when utilized, means “including, but not necessarily limited to”; it specifically indicates open-ended inclusion or membership in the so-described combination, group, series and the like.

The disclosure will now be described in relation to an electronic device with a power switch system.

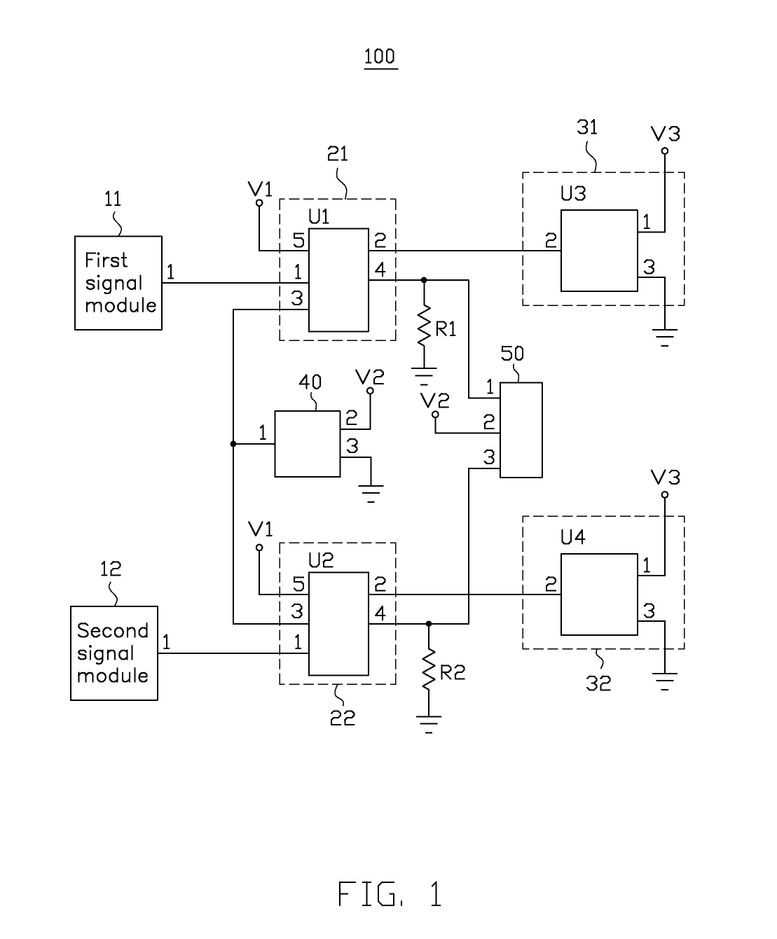

FIG. 1 shows an embodiment of a motherboard 100. The motherboard 100 can comprise a first signal module 11, a second signal module 12, a first switch module 21, a second switch module 22, a first enable module 31, a second enable module 32, an input interface 40 and a control module 50.

A first signal terminal of the first switch module 21 is coupled to a first signal terminal of the first signal module. A first signal of the second switch module 22 is coupled to a first signal terminal of the second signal module 12. A third signal module of the second switch module 22 is coupled to a third terminal of the first switch module 21.

The first signal terminal of the first enable module 31 is coupled to the second signal terminal of the first switch module 21. A first signal terminal of the second enable module 32 is coupled to a second signal terminal of the second switch module 22.

The input interface 40 is coupled to a first input terminal of the first switch module 21. The input interface 40 is coupled to a first input terminal of the second switch module 22.

The control module 50 is coupled to a third signal terminal of the first switch module 21. The control module 50 is also coupled to a third signal terminal of the second switch module 22. When the control module 50 outputs a first control signal to the first switch module 21, the second signal terminal of the first switch module 21 is coupled to the first signal terminal of the first switch module 21. When the control module 50 outputs a second control signal to the first switch module 21, the second signal terminal of the first switch module 21 is coupled to the third signal terminal of the first switch module 21.

When the control module 50 outputs the first control signal to the second switch module 22, the second signal terminal of the second switch module 22 is coupled to the first signal terminal of the second switch module 22. When the control module 50 outputs the second control signal to the second switch module 22, the second signal terminal of the second switch module 22 is coupled to the third signal terminal of the second switch module 22.

In the embodiment, the first switch module 21 can comprise a first switch chip U1. The second switch module 22 can comprise a second switch chip U2. The first enable module 31 can comprise a first enable chip U3. The second enable module 32 can comprise a second enable chip U4.

A signal pin 1 of the first switch chip U1 is coupled to a signal pin 1 of the first signal module 11. A signal pin 2 of the first switch chip U1 is coupled to a signal pin 2 of the first enable chip U3. A signal pin 3 of the first switch chip U1 is coupled to a signal pin 3 of the second switch chip U2. The signal pin 3 of the first switch chip U1 is also coupled to a signal pin 1 of the input interface 40. A ground pin 4 of the first switch chip U1 is grounded through a resistor R1. The ground pin 4 of the first switch chip U1 is also coupled to a signal pin 1 of the control module 50. A power pin 5 of the first switch chip U1 is coupled to a power terminal V1.

A signal pin 1 of the second switch chip U2 is coupled to a signal pin 1 of the first signal module 11. A signal pin 2 of the second switch chip U2 is coupled to a signal pin 2 of the second enable chip U4. A ground pin 4 of the second switch chip U2 is grounded through a resistor R2. The ground pin 4 of the second switch chip U2 is also coupled to a signal pin 3 of the control module 50. A power pin 5 of the second switch chip U2 is coupled to the power terminal V1.

A power pin 2 of the input interface 40 is coupled to a power terminal V2. A ground pin 3 of the input interface 40 is grounded.

A power pin 2 of the control module 50 is coupled to the power terminal V2.

A power pin 1 of the first enable chip U3 is coupled to a power terminal V3. A ground pin 3 of the first enable chip U3 is grounded.

A power pin 1 of the second enable chip U4 is coupled to a power terminal V3. A ground pin 3 of the second enable chip U4 is grounded.

In the embodiment, the first enable chip U3 and the second enable chip U4 are flash memory chips. The first enable chip U3 can be programmed to enable the first signal module 11. The second enable chip U4 can be programmed to enable the second signal module 12.

When the input interface 40 is coupled to a programmer, the power terminal V2 receives a voltage from the programmer. The signal pin 1 of the input interface 40 receives a signal for programming. The power pin 2 of the control module 50 receives the voltage from the programmer.

When the input interface 40 is not coupled to the programmer, the power terminal V2 does not receive the voltage. The ground pin 4 of the first switch chip U1 is grounded through the resistor R1. The ground pin 4 of the first switch chip U1 is at a low level. The signal pin 1 of the first switch chip U1 is coupled to the signal pin 2 of the first switch chip U2. The ground pin 4 of the second switch chip U2 is grounded through the resistor R2. The ground pin 4 of the second switch chip U2 is at a low level. The signal pin 1 of the second switch chip U2 is coupled to the signal pin 2 of the second switch chip U2.

When the first enable chip U3 is to be programmed, the power pin 2 of the control module 50 is coupled to the signal pin 1 of the control module 50. The ground pin 4 of the first switch chip U1 is at a high level. The signal pin 1 of the first switch chip U1 is coupled to the signal pin 3 of the first switch chip U1. The signal for programming is transmitted to the first enable chip U3 through the first switch chip U1.

When the second enable chip U3 is to be programmed, the power pin 2 of the control module 50 is coupled to the signal pin 3 of the control module 50. The ground pin 4 of the second switch chip U2 is at a high level. The signal pin 1 of the switch chip U2 is coupled to the signal pin 3 of the second switch chip U2. The signal for programming is transmitted to the second enable chip U4 through the second switch chip U2.

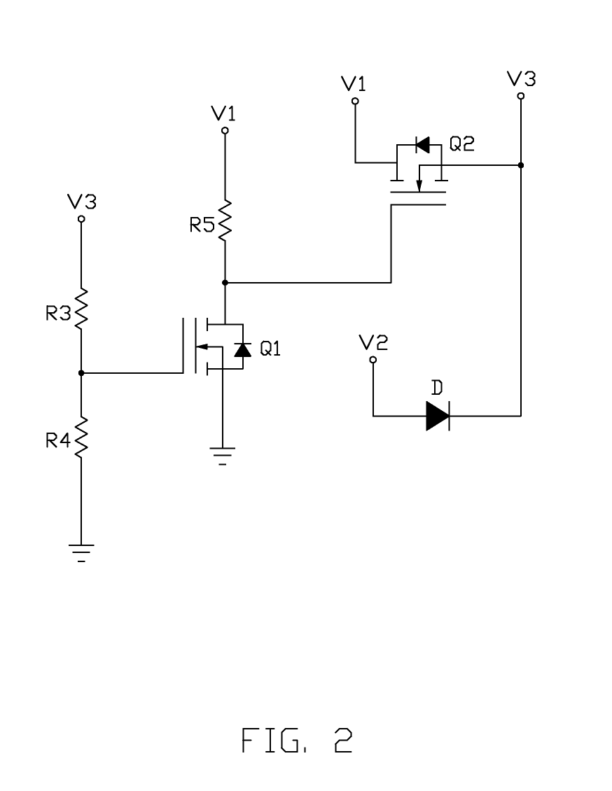

FIG. 2 shows an embodiment of the power terminals V1-V3 of the motherboard in FIG. 1. The power terminal V2 is grounded through a resistor R3 and a resistor R4 in that order. A node A between the resistor R3 and the resistor R4 is coupled to a grid of a field effect transistor (FET) Q1. A source of the FET Q1 is grounded. A drain of FET Q1 is coupled to the power terminal Q1 through a resistor R5. The drain of the FET Q1 is also coupled to a grid of a FET Q2. A drain of the FET Q2 is coupled to the power terminal V3. A source of the FET Q2 is coupled to a cathode of a diode D. An anode of the diode D is coupled to the power terminal V2.

When the power terminal V2 does not receive the voltage from the programmer, the grid of the FET Q1 is at a low level. The source of the FET Q1 is disconnected from the drain of the FET Q1. The power terminal V1 outputs a high level signal to the grid of the FET Q2. The source of the FET Q2 is coupled to the drain of the FET Q2. The power terminal V3 receives a voltage from the power terminal V1.

When the power terminal V2 receives the voltage from the programmer, the grid of the FET Q1 is at a high level. The drain of the FET Q1 is coupled to the source of the FET Q1. The power terminal V1 is grounded through the resistor R5. The grid of the FET Q2 is at a low level. The source of the FET Q2 is disconnected from the drain of the FET Q2. The power terminal V2 outputs the voltage from the programmer to the power terminal V3 through the diode D.

In the embodiment, the control module 50 is a jumper. In other embodiments, the control module 50 can be a single-pole double-throw switch.

In the embodiment, the FET Q1 is an n-channel FET. The FET Q2 is an n-channel FET.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A motherboard, comprising:
a first switch module and a second switch module, a first signal terminal of the first switch module coupled to a first signal terminal of the first signal module, a first signal terminal of the second switch module coupled to a first signal terminal of the second signal module, a second signal terminal of the second switch module coupled to a second signal terminal of the first switch module;
a first enable module and a second enable module, a first signal terminal of the first enable module coupled to a third signal terminal of the first switch module, a first signal terminal of the second enable module coupled to a third signal terminal of the second switch module;
an input interface coupled to a first input terminal of the first switch module and a first input terminal of the second switch module; and
a control module coupled to the second signal terminal of the first switch module and the second signal terminal of the second switch module;
wherein the control module is configured such that in event the control module outputs a first control signal to the first switch module, the third signal terminal of the first switch module is coupled to the first signal terminal of the first switch module, and in event the control module outputs a second control signal to the first switch module, the third signal terminal of the first switch module is coupled to the second signal terminal, and in event the control module outputs the first control signal to the second switch module, the first signal terminal of the second switch module is coupled to the third signal terminal of the second switch module, and in event the control module outputs the second control signal to the second switch module, the third signal terminal of the second switch module is coupled to the second signal terminal of the second switch module.

2. The motherboard as claim 1, wherein the first switch module comprises a first switch chip, the second switch module comprises a second switch chip, the first enable module comprises a first enable chip, the second enable module comprises a second enable chip; a first signal pin of the first switch chip is coupled to a first signal pin of the first signal module, a second signal pin of the first switch chip is coupled to a second signal pin of the first enable chip, a third signal chip of the first switch chip is coupled to a third signal pin of the second switch chip, the third signal pin of the first switch chip is coupled to a first signal pin of the input interface, a ground pin of the first switch chip is grounded through a first resistor, the ground pin of the first switch chip is coupled to a first signal pin of the control module, a power pin of the first switch chip is coupled to a first power terminal.

3. The motherboard as claim 2, wherein a first signal pin of the second switch chip is coupled to the first signal pin of the first signal module, a second signal pin of the second switch chip is coupled to the second signal pin of the second enable chip, a ground pin of the second switch chip is grounded through a second resistor, the ground pin of the second switch is also coupled to the second signal pin of the control module, a power pin of the second switch chip is coupled to the first power terminal.

4. The motherboard as claim 3, wherein a power pin of the input interface is coupled to a second power terminal, a ground pin of the input interface is grounded, a power pin of the control module is coupled to the second power terminal, a power pin of the first enable chip is coupled to a third power terminal, a ground pin of the first enable chip is grounded, a power pin of the second enable chip is coupled to the third power terminal, a ground pin of the second enable chip is grounded.

5. The motherboard as claim 4, wherein the second power terminal is grounded through a third resistor and a fourth resistor in that order, a node between the third resistor and the fourth resistor is coupled to a grid of the first field effect transistor (FET), a drain of the first FET is coupled to the first power terminal through a fifth resistor, a source of the first FET is grounded, a drain of the first FET is coupled to a grid of a second FET, a drain of the second FET is coupled to the first power terminal, a source of the second FET is coupled to the third power terminal, the third power terminal is coupled to a cathode of a diode, an anode of the diode is coupled to the second power terminal.

6. The motherboard as claim 5, wherein the first FET is an n-channel FET.

7. The motherboard as claim 5, wherein the second FET is an n-channel FET.

8. The motherboard as claim 4, wherein the control module is a jumper.

9. The motherboard as claim 4, wherein the control module is a single-pole double-throw switch.

10. The motherboard as claim 4, wherein the first enable chip and the second enable chip are flash memory chips.
